(19) United States
(12) Patent Application Publication
(10) Pub. No.: US 2025/0014903 A1
(43) Pub. Date: Jan. 9, 2025

(54) IMPLANTATION METHOD

(71) Applicant: Fraunhofer-Gesellschaft zur Förderung der angewandten Forschung e.V., Munich (DE)

(72) Inventor: Christian Giese, Freiburg (DE)

(73) Assignee: Fraunhofer-Gesellschaft zur Förderung der angewandten Forschung e.V., Munich (DE)

(21) Appl. No.: 18/753,794

(22) Filed: Jun. 25, 2024

(30) Foreign Application Priority Data
Jul. 3, 2023 (DE) 102023206269.0

(51) Int. Cl. H01L 21/265

(52) U.S. Cl. CPC H01L 21/26586; H01L 21/26546

(57) ABSTRACT

Methods of implantation are provided including the following steps: providing a substrate, which contains or consists of a semiconductor material; producing at least one raised structure on the substrate; implanting a dopant at least in a partial region of the raised structure; wherein the ion beam used for implantation is incident at an angle from about 80° to about 90° in relation to the normal vector of the substrate.

This application claims priority under 35 USC § 119 to German Patent Application No. 102023206269.0, filed Jul. 3, 2023, which is hereby incorporated by reference.

### TECHNICAL FIELD

The invention relates to an implantation method comprising the following steps: providing a substrate containing or consisting of a semiconductor material, producing at least one raised structure on the substrate, and implanting a dopant at least in a portion of the raised structure.

### BRIEF DESCRIPTION OF THE DRAWINGS

The examples may be better understood with reference to the following drawings and description. The components in the figures are not necessarily to scale. Moreover, in the figures, like-referenced numerals designate corresponding parts throughout the different views.

FIG. 1 shows a first embodiment of the proposed method;

FIG. 2 shows a second embodiment of the proposed method; and

FIG. 3 shows a third embodiment of the proposed method.

### DETAILED DESCRIPTION

The invention relates to an implantation method comprising the following steps: providing a substrate containing or consisting of a semiconductor material, producing at least one raised structure on the substrate, and implanting a dopant at least in a portion of the raised structure.

It is known from P. Maletinsky, S. Hong, M. Grinolds, B. Hausmann, M. Lukin, R. Walsworth, M. Loncar, A. Yacoby: “A robust scanning diamond sensor for nanoscale imaging with single nitrogen-vacancy centers”, Nature Nanotechnology 7 (2012) 320, to produce color centers in semiconducting diamond. A color center of this type can be an NV center, for example. This center consists of a nitrogen atom and an adjacent vacancy in the crystal lattice of the diamond. NV centers can be used, for example, to determine the strength of a magnetic field. For this purpose, the splitting of a doublet state in the magnetic field is detected by spectroscopic measurement. If one or a few NV centers are concentrated in a small partial volume of the diamond, the determination of the magnetic field can be recorded with a high spatial resolution, for example less than 1 μm or less than 100 nm. In addition, NV centers can be used as Q bits in quantum information technology.

These known uses of color centers presuppose that color centers can be produced in a small, defined volume of a larger semiconductor device. According to the prior art, this is usually done by implantation with a focused ion beam or after the application of a hard mask, the ion beam striking along the normal vector of the semiconductor substrate and it being possible to implant the ions in the unmasked partial areas. However, this method has the disadvantage that the production of the smallest openings in the hard mask is accompanied by great effort.

On the basis of the prior art, the object of the invention is therefore to provide a method by means of which an implantation can be carried out in a simple and reliable fashion in narrowly defined spatial areas.

According to the invention, a method is proposed which contains at least the following steps. First, a substrate is provided which contains or consists of a semiconductor material. The semiconductor material can be e.g. silicon, germanium, a III-V compound semiconductor, a group III nitride or diamond. The semiconductor material can be arranged as a thin film on a carrier material. In other embodiments of the invention, the substrate can consist entirely of the semiconductor material. In addition, the substrate can be coated and/or contain a dopant to render possible a predeterminable conductivity of the substrate.

At least one raised structure is then produced on the substrate. The raised structure can be a MESA or a cantilever, for example. These structures can be obtained in a manner known per se by masking and etching the substrate. In other embodiments of the invention, the raised structures can be produced by masking and depositing further layers on the substrate, e.g. by means of MBD or MOCVD. The invention does not teach the use of a certain structure as a solution principle. However, the structure is raised within the meaning of the present description if it protrudes at least partially beyond a plane defined by the substrate surface. The raised structure contains at least one semiconductor material which can be the material of the substrate or another material.

The method also comprises at least one method step of implanting a dopant. In some embodiments of the invention, the dopant can be used to produce a predeterminable conductivity of the semiconductor material in at least a partial region or a partial volume. In other embodiments of the invention, the dopant can form at least one color center in the crystal lattice of the semiconductor material of the substrate. According to the invention, the dopant is introduced by implantation, i.e. by ionizing the dopant and accelerating it to a predeterminable kinetic energy by means of electric fields and directing it onto the substrate.

According to one aspect of the invention, it is proposed that the ion beam used for implantation is incident at an angle from about 80° to about 90° in relation to the normal vector of the substrate. In contrast to known implantation methods in which the ion beam is directed onto the substrate approximately parallel to the normal vector, it is thus proposed according to the invention that there is approximately a right angle between the normal vector and the direction of incidence of the ion beam. This feature has the effect that the ions can be implanted in the front sides or tips of the raised structures. In this case, the volume of the implanted region is defined by the penetration depth and the cross-sectional area of the front face. In this way, it is also possible to implant even very small partial volumes of the raised structure without having to deposit complex and comparatively thick masks on the substrate or the raised structures.

If the angle between the direction of incidence and the normal vector is slightly less than 90°, it is also possible to implant in a plurality of raised structures arranged on the substrate. This can further increase the productivity of the proposed method.

In some embodiments of the invention, the ion beam used for implantation can be incident at an angle from about 85° to about 90° in relation to the normal vector of the substrate. In other embodiments of the invention, the ion beam used for implantation can be incident at an angle from about 84° to about 89° in relation to the normal vector of the substrate. In yet other embodiments of the invention, the ion beam used for implantation can be incident at an angle from about 85° to about 88° in relation to the normal vector of the substrate. In some embodiments of the invention, the ion beam used for implantation can be incident at an angle from about 88° to about 89° in relation to the normal vector of the substrate. In these angular ranges, the raised structures can at least partially shadow themselves or one another so that only partial regions are implanted in each raised structure regardless of the extension thereof on the substrate surface. At the same time, the entire raised structures arranged on the surface of even large substrates can be implanted in just one work step so that the method can also be used to produce large numbers of semiconductor devices even in a short time.

In some embodiments of the invention, the ion beam used for implantation can have an energy from about 5 keV to about 1 MeV. In other embodiments of the invention, the ion beam used for implantation can have an energy from about 20 keV to about 100 keV. In yet other embodiments of the invention, the ion beam used for implantation can have an energy from about 20 keV to about 50 keV. In still other embodiments of the invention, the ion beam used for implantation can have an energy from about 5 keV to about 20 keV or from about 5 keV to about 15 keV.

In some embodiments of the invention, the ion beam used for implantation can contain nitrogen and/or silicon and/or germanium and/or lead and/or tin. These materials allow the production of color centers, particularly in diamond. They can be used in a variety of ways in quantum technology, for example in quantum computing, for quantum communication or for detecting electric or magnetic fields. In this case, the energy of the ion beam can be selected in such a way that the ions are at least partially implanted in the diamond, even if this diamond is only arranged as a layer on a substrate that is made of another material.

In some embodiments of the invention, the ion beam used for implantation can contain or consist of nitrogen and/or boron and/or sulfur and/or phosphorus and/or aluminum. These materials can be used as donor or acceptor and thus allow the conductivity of the substrate or the implanted partial volumes to be adjusted to predeterminable target values.

In some embodiments of the invention, the ion beam used for implantation can be collimated. On the one hand, this reduces the angular divergence so that uncontrolled implantation of the dopants is reduced or avoided. In addition, a collimated beam can cover a larger area on the substrate so that a plurality of raised structures can be implanted at the same time.

In some embodiments of the invention, a plurality of raised structures can be produced in succession in the direction of incidence of the ion beam. This allows a better utilization of the semiconductor material of the substrate. In some embodiments of the invention, a partial area of a first raised structure can shade a partial area of a second raised structure against the incident ion beam. For this purpose, the second raised structure can be located behind the first raised structure, as viewed in the direction of incidence of the ion beam. Due to the self-shadowing of a plurality of components, partial regions or partial volumes of the raised structures can be selectively implanted over the entire surface of the substrate without the need to produce and structure complex hard masks on the substrate.

In some embodiments of the invention, the upper side of the raised structure that faces away from the substrate can be at least partially provided with a mask. In some embodiments of the invention, this mask can also be used during at least one manufacturing step for the production of at least one raised structure and after producing the raised structure can initially remain thereon and optionally be removed after the implantation. Due to the grazing incidence of the ion beam used for implantation, a thin mask of e.g. 10 nm to about 100 nm is sufficient in this case to prevent a penetration of the ions used for implantation into the masked regions.

In some embodiments of the invention, the method can include the additional method step of producing at least one raised barrier on the first side of the substrate. The barrier can also be produced, for example, by masking and etching or by depositing additional material on the substrate. In some embodiments of the invention, the barrier can contain a recess. The longitudinal extension of the barrier can here be approximately parallel to the extension of the raised structures. The barrier can be produced so as to be at a distance from the raised structures or at a distance from a raised structure. The barrier thus stands on the substrate in the manner of a wall and is not deposited flat in the plane of the substrate. This feature has the effect that implantation can take place through the barrier or through the recess produced in the barrier and in this way remains spatially limited. However, in this case too, the implantation takes place approximately orthogonally to the normal vector of the substrate and not parallel to the normal vector in a manner known per se.

In some embodiments of the invention, the ion beam used for implantation can be incident at an angle from about 45° to about 90° in relation to the longitudinal extension of the raised structure and/or the barrier. Smaller angles here cause an extension of the recess that decreases in the projection so that the implantation region can be further reduced.

In some embodiments of the invention, the ion beam used for implantation can be incident at an angle from about 45° to about 85° in relation to the longitudinal extension of the raised structure and/or barrier. In other embodiments of the invention, the ion beam used for implantation can be incident at an angle from about 45° to about 80° in relation to the longitudinal extension of the raised structure and/or barrier. In yet other embodiments of the invention, the ion beam used for implantation can be incident at an angle from about 60° to about 80° in relation to the longitudinal extension of the raised structure and/or barrier. This renders possible to control the size or volume of the raised structure region to be implanted.

The invention will be explained in more detail below with reference to drawings without limiting the general concept of the invention.

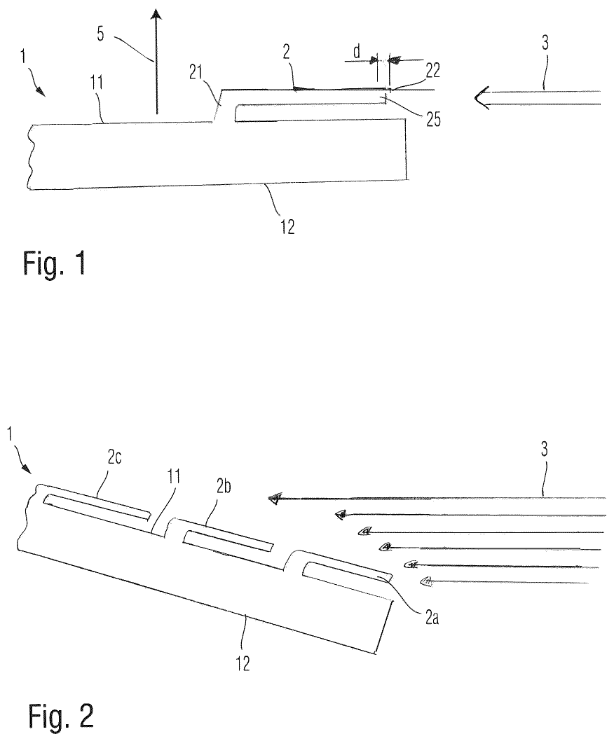

A first embodiment of the proposed implantation method is explained in more detail with reference to FIG. 1. FIG. 1 here shows a substrate 1 in a sectional view and the ion beam 3 used for implantation.

FIG. 1 shows a substrate 1 having a first side 11 and an opposite second side 12. The normal vector 5 of the plane defined by substrate 1 is also shown. Substrate 1 can contain or consist of a semiconductor material. In particular, the semiconductor material can be selected from silicon, a III-V compound semiconductor or diamond. The substrate 1 can be homogeneous. In other embodiments of the invention, the substrate 1 can have a coating, for example a III-V compound semiconductor can be deposited on sapphire. In other embodiments of the invention, a diamond layer can be deposited homoepitaxially or heteroepitaxially on diamond or silicon. The material of substrate 1 can be completely or partially provided with a dopant.

As also shown in FIG. 1, a raised structure 2 was produced on the substrate 1. In the illustrated exemplary embodiment, the raised structure 2 is a collar or a cantilever having a first end 21 and an opposite second end 22. The cantilever runs parallel to the first side 11 of the substrate 1 or lies within a plane parallel to the substrate plane. The first end 21 is firmly connected to the substrate 1 via a connecting web. The opposite second end 22 protrudes freely into the half-space adjacent to the substrate 1.

The raised structure 2 according to FIG. 1 can, for example, be designed as a waveguide that transports light from the second end 22 to the first end 21. A doped region 25 can be present at the second end 22 and contains at least one or also more color centers, for example NV centers.

If the NV centers shall be used to determine a magnetic field, the spatial resolution is improved by the fact that the doped region 25 occupies the smallest possible volume of the raised structure 2. According to the prior art, this would be achieved by providing the first side 11 of the substrate 1 with a comparatively thick hard mask which leaves the second end 22 of the raised structure free so that the foreign atoms required to produce the color centers can be implanted parallel to the normal vector 5.

In contrast thereto, it is proposed according to the invention that the ion beam 3 used for the implantation is incident at an angle from about 80° to about 90° in relation to the normal vector 5 of the substrate 1. This limits the area available for implantation in the beam direction to the cross-sectional area of the raised structure 2. The penetration depth d is limited by the kinetic energy of the impinging ions. This results in a spatially sharply limited volume of the implanted region 25 without the need for complex processing by depositing, structuring and removing hard masks. Masks remaining from the previous production of the at least one raised structure 2 can optionally remain on the raised structure 2 during implantation. However, this is not absolutely necessary.

The method according to the invention permits a very good spatial localization of the doped regions 25 with little equipment effort. Therefore, it is advantageous for the ion beam 3 to be collimated. For the purposes of the present invention, a collimated beam is understood to mean a small angular divergence of the incoming ions so that an undesired lateral impact of the ions on the raised structure 2 is avoided.

A second embodiment of the present invention is explained in more detail by means of FIG. 2. Identical components of the invention are provided with identical reference signs so that the following description is limited to the essential differences.

FIG. 2 also shows the cross-section through a substrate 1. As can be seen from FIG. 2, a plurality of raised structures 2a, 2b and 2c are produced one behind the other on the substrate 1 in the direction of incidence of the ion beam 3. In this connection, it should be noted that the illustrated three raised structures are merely exemplary. In other embodiments of the invention, the number can also be greater or less.

The angle between the normal vector of the substrate 1 and the ion beam 3 is greatly enlarged in FIG. 2 for the purpose of clarification. In real embodiments of the method, the angle between the normal vector and the ion beam would be closer to 90° in order to allow a grazing incidence of the ions on the first side 11 of the substrate 1 in this way. As shown in FIG. 2, a grazing incidence of this type results in a raised structure 2a at the front that partially shades the raised structure 2b behind it. Similarly, the raised structure 2c is partially shaded by the raised structure 2b in front of it in the direction of incidence. In this way, doped regions 25 can be created within the raised structures 2a, 2b and 2c without a masking being absolutely necessary. The effort involved in applying a mask can therefore be saved. By tilting the substrate in one direction or the other, the position of the doped region 25 within the longitudinal extension of the raised structure 2 can be controlled. The angle of incidence of the ion beam 3 is in this case selected in such a way that an undesired implantation in undoped regions of the raised structures 2a, 2b, 2c is avoided, for example because the ions leave the raised structures 2a, 2b, 2c again in the case of grazing incidence or are implanted in such a shallow manner that this layer can be removed by subsequent etching.

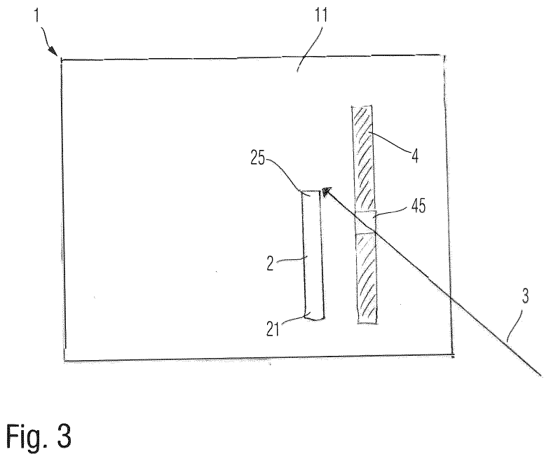

A third embodiment of the invention is explained in more detail by means of FIG. 3. FIG. 3 shows a top view of the first side 11 of a substrate 1. A raised structure 2 is shown on the substrate 1 by way of example. Of course, the number of raised structures 2 can also be greater in order to produce a plurality of components in a single operation in this way.

The raised structure 2 according to FIG. 3 also has a longitudinal extension with a first end 21 and an opposite end 22. A doped region 25 shall be produced at the second end 22. For this purpose, a barrier 4 is produced on the first side 11 of the substrate 1 parallel to and at a distance from the raised structure 2. The barrier 4 can, for example, be produced by masking and etching at the same time as the raised structure 2. A recess 45 is located within the barrier 4. The ion beam 3 used for implantation is incident at an angle from about 45° to about 90° in relation to the longitudinal extension of the barrier 4 and partially penetrates the recess 45. Another portion of the incident ions is stopped in the barrier 4 so that this portion does not reach the raised structure 2. The relative position of the recess 45, the width thereof and the angle of incidence can be selected in such a way that the spatial extension of the doped region 45 and the position thereof reach predeterminable values.

Of course, the invention is not restricted to the illustrated embodiments. The above description should therefore not be regarded as limiting but as explanatory. This does not exclude the presence of further features. Insofar as the claims and the above description define “first” and “second” embodiments, this designation is used to distinguish between two similar embodiments without establishing an order of priority.

To clarify the use of and to hereby provide notice to the public, the phrases “at least one of <A>, <B>, . . . and <N>” or “at least one of <A>, <B>, . . . or <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

What is claimed is:

1. A method of implantation comprising:
providing a substrate, which contains or consists of a semiconductor material;
producing at least one raised structure on the substrate;
implanting a dopant at least in one partial region of the raised structure;
wherein
the ion beam used for implantation is incident at an angle from about 80° to about 90° in relation to the normal vector of the substrate.

2. The method of claim 1, wherein the ion beam used for implantation is collimated.

3. The method of claim 1, wherein the ion beam used for implantation is incident at an angle from about 85° to about 90° in relation to the normal vector of the substrate or in that the ion beam used for implantation is incident at an angle from about 84° to about 89° in relation to the normal vector of the substrate or in that the ion beam used for implantation is incident at an angle from about 85° to about 88° in relation to the normal vector of the substrate or in that the ion beam used for implantation is incident at an angle from about 88° to about 89° in relation to the normal vector of the substrate.

4. The method of claim 1, wherein the ion beam used for implantation contains or consists of nitrogen and/or silicon and/or germanium and/or lead and/or tin and/or boron and/or sulfur and/or phosphorus and/or aluminum.

5. The method of claim 1, wherein the upper side of the raised structure that faces away from the substrate is at least partially provided with a mask.

6. The method of claim 1, wherein the ion beam used for implantation has
an energy from about 5 keV to about 1 MeV or
an energy from about 20 keV to about 100 keV or
an energy from about 20 keV to about 50 keV or
an energy from about 5 keV to about 20 keV or
an energy from about 5 keV to about 15 keV.

7. The method of claim 1, wherein a plurality of raised structures are produced in succession in the direction of incidence of the ion beam.

8. The method of claim 7, wherein a partial area of a first raised structure shades a partial area of a second raised structure against the incident ion beam.

9. The method of claim 1, further containing the method step of producing at least one raised barrier on the substrate.

10. The method of claim 9, wherein the barrier contains at least one recess.

11. The method of claim 9, wherein the raised structure and/or the barrier have a longitudinal extension and the ion beam used for implantation is incident at an angle from about 45° to about 90° in relation to the longitudinal extension of the raised structure and/or the barrier.

12. The method of claim 11, wherein the ion beam used for implantation is incident at
an angle from about 45° to about 85° or
an angle from about 45° to about 80° or
an angle from about 60° to about 80° or
in relation to the longitudinal extension of the raised structure and/or the barrier.

13. The method of claim 1, wherein the substrate contains or consists of diamond.
